(19) United States
(12) Patent Application Publication
(10) Pub. No.: US 2024/0128217 A1
(43) Pub. Date: Apr. 18, 2024

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Yi-Jung CHEN, Hsinchu (TW); Chen Chiang YU, Hsinchu (TW); Wei-An TSAO, Hsinchu (TW); Tsung-Fu TSAI, Hsinchu (TW); Szu-Wei LU, Hsinchu (TW); Chung-Shi LIU, Hsinchu (TW)

(73) Assignee: Taiwan Semiconductor Manufacturing Company, Ltd., Hsinchu (TW)

(21) Appl. No.: 18/099,555

(22) Filed: Jan. 20, 2023

Related U.S. Application Data
(60) Provisional application No. 63/416,110, filed on Oct. 14, 2022.

(51) Int. Cl. H01L 23/00

(52) U.S. Cl. CPC H01L 24/13; H01L 24/03; H01L 24/05; H01L 24/08; H01L 24/11; H01L 24/16; H01L 24/80; H01L 24/81; H01L 2224/0345; H01L 2224/03912; H01L 2224/05026; H01L 2224/05073; H01L 2224/05082; H01L 2224/05147; H01L 2224/05556; H01L 2224/05562; H01L 2224/05567; H01L 2224/05568; H01L 2224/05573; H01L 2224/05666; H01L 2224/05686; H01L 2224/08147; H01L 2224/1145; H01L 2224/1161; H01L 2224/11912; H01L 2224/13005; H01L 2224/13016; H01L 2224/13147; H01L 2224/80357; H01L 2224/80379; H01L 2224/81201; H01L 2224/8134; H01L 2224/81931; H01L 2924/04941; H01L 2924/059; H01L 2924/20105; H01L 2924/20106; H01L 2924/20107

(57) ABSTRACT

A semiconductor device includes a first semiconductor die and a second semiconductor die connected to the first semiconductor die. Each of the first semiconductor die and the second semiconductor die includes a substrate, a conductive bump formed on the substrate and a conductive contact formed on the conductive bump. The conductive contact has an outer lateral sidewall, there is an inner acute angle included between the outer lateral sidewall and the substrate is smaller than 85°, and the conductive contact of the first semiconductor die is connected opposite to the conductive contact of the second semiconductor die.

### PRIORITY CLAIM AND CROSS-REFERENCE

This application claims the benefit of U.S. provisional application Ser. No. 63/416,110, filed Oct. 14, 2022, the subject matter of which is incorporated herein by reference.

### BACKGROUND

Each of two semiconductor components includes a conductive contact, and the conductive contact of one of two semiconductor components may be connected to the conductive contact of another of two semiconductor components by bump-to-bump bonding technique. However, a combination between the two conductive contacts is affected by a junction characteristic, a heating temperature, etc.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic diagram of a semiconductor device according to an embodiment of the present disclosure;

FIG. 1B illustrates a schematic diagram of a cross-sectional view of the semiconductor device of FIG. 1A in a direction 1B-1B′;

FIG. 2 illustrates a schematic diagram of a semiconductor device according to another embodiment of the present disclosure;

FIG. 3 illustrates a schematic diagram of a semiconductor device according to another embodiment of the present disclosure;

FIG. 4 illustrates schematic diagram of a semiconductor device according to another embodiment of the present disclosure;

FIGS. 5A to 5G. FIGS. 5A to 5G illustrate schematic diagrams of a manufacturing method of the semiconductor device of FIG. 1A;

FIGS. 6A to 6B illustrate schematic diagrams of another manufacturing method of the semiconductor device of FIG. 1A;

FIGS. 7A to 7D illustrate schematic diagrams of a manufacturing method of the semiconductor device of FIG. 2;

FIGS. 8A to 81) illustrate schematic diagrams of a manufacturing method of the semiconductor device of FIG. 3; and

FIGS. 9A to 9D illustrate schematic diagrams of a manufacturing method of the semiconductor device of FIG. 4.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath.” “below.” “lower.” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

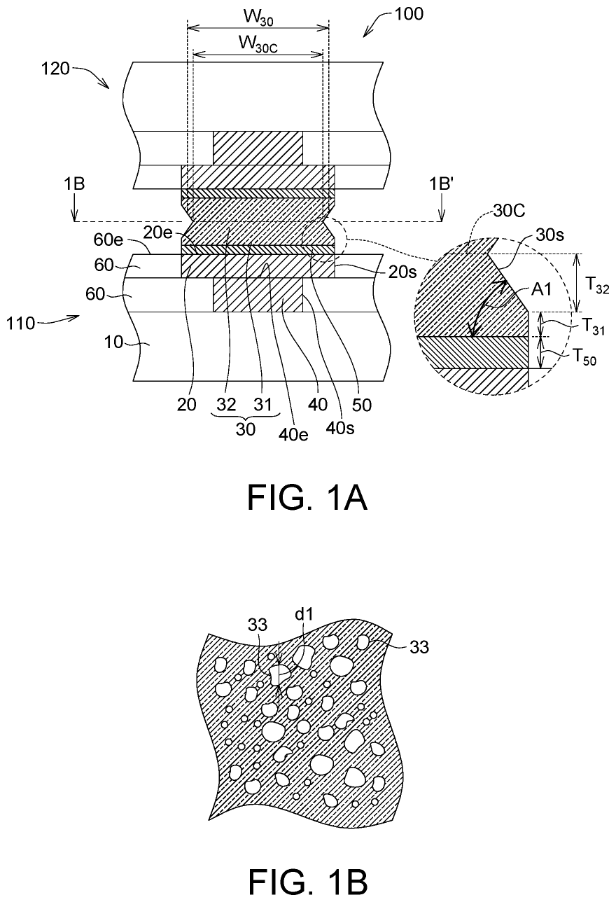

Referring to FIGS. 1A and 18. FIG. 1A illustrates a schematic diagram of a semiconductor device 100 according to an embodiment of the present disclosure, and FIG. 1B illustrates a schematic diagram of a cross-sectional view of the semiconductor device 100 of FIG. 1A in a direction 1B-1B′.

As illustrated in FIG. 1A, the semiconductor device 100 includes a first semiconductor die 110 and a second semiconductor die 120. The first semiconductor die 110 and the second semiconductor die 120 may be connected by using bump-to-bump bonding technique or Cu-to-Cu bonding technique. Each of the first semiconductor die 110 and the second semiconductor die 120 includes a substrate 10, at least one conductive bump 20, at least one conductive contact 30, at least one conductive via 40, at least one seed layer 50 and at least one dielectric layer 60. The conductive contact 30 of the first semiconductor die 110 and the conductive contact 30 of the second semiconductor die 120 are connected to each other by using bump-to-bump bonding technique or Cu-to-Cu bonding technique.

As illustrated in FIG. 1A, the conductive contact 30 has an outer lateral sidewall 30s. The conductive contact 30 is a tapered contact. Furthermore, the conductive contact 30 has a width W₃₀ gradually decreasing in a direction away from the seed layer 50. The conductive contact 30 of the first semiconductor die 110 and the conductive contact 30 of the second semiconductor die 120 are connected in a connection 30C, and the connection 30C has a width W_{30c} ranging between, for example, 0.6 micrometers (μm) to 2.5 μm.

As illustrated in FIG. 1A, there is an inner acute angle A1 included between the outer lateral sidewall 30s and the conductive bump 20 is smaller than 85°. In an embodiment, the inner acute angle A1 may range between 55° and 80°, for example, 55°, 56°, 57°, 58°, 59°, 60°, 61°, 62°, 63°, 64°, 65°, 66°, 67°, 68°, 69°, 70°, 71°, 72°, 73°, 74°, 75°, 76°, 77°, 78°, 79°, 80°, etc., and accordingly the conductive contact 30 may be successfully formed.

As illustrated in FIG. 1A, the conductive contact 30 includes a base layer 31 and a protrusion 32 formed on the base layer 31. The protrusion 32 has the outer lateral sidewall 30s, there is the inner acute angle A1 included between the outer lateral sidewall 30s and the base layer 31 is greater than 85°.

As illustrated in FIG. 1A, the protrusion 32 of the conductive contact 30 has a protrusion thickness T₃₂, the seed layer 50 has a seed thickness T₅₀, and the protrusion thickness T₃₂ is, for example, 3 times to 10 times of the seed thickness T₅₀. If the protrusion thickness T₃₂ is smaller than 3 times of the seed thickness T₅₀, the strength of the protrusion thickness T₃₂ is not enough to support the reliable bonding. If the protrusion thickness T₃₂ is greater than 10 times of the seed thickness T₅₀, the formation of the conductive contact 130 is time-consuming. In an embodiment, the protrusion thickness T₃₂ may range between 1 μm and 6 μm, for example, 2 μm, 3 μm, 4 μm, 5 μm, etc. Similarly, the base layer 31 has a base thickness T₃₁, and the protrusion thickness T₃₂ is, for example, 3 times to 10 times of the base thickness T₃₁.

As illustrated in FIG. 1B, the conductive contact 30 has a fine metallographic structure. Furthermore, the conductive contact includes a plurality of grains 33, and each of at least one of the grains 33 has a diameter d1 ranging between 2 nanometers (nm) to 100 nm, such as 2 nm, 3 nm, 4 nm, 5 nm, 6 nm, 7 nm, 8 nm, 9 nm, 10 nm, 11 nm, 12 nm, . . . , 20 nm, . . . , 100 nm, etc.

As illustrated in FIG. 1A, the substrate 10 is, for example, silicon wafer. The conductive via 40 is formed on the substrate 10. The dielectric layer 60 covers a lateral surface 40s of the conductive via 40 and exposes a terminal surface 40e of the conductive via 40, and the conductive bump 20 is formed on the terminal surface 40e of the conductive via 40. The dielectric layer 60 covers a lateral surface 20s of the conductive bump 20 and exposes a terminal surface 20e of the conductive bump 20. The seed layer 50 is formed on the terminal surface 20e of the conductive bump 20, and the conductive contact 30 is formed on the seed layer 50. In the present embodiment, the seed layer 50 and the conductive contact 30 protrude with respect to a terminal surface 60e of the outermost dielectric layer 60.

In an embodiment, the conductive bump 20 is, for example, a bump metal (BPM). The conductive via 40 is, for example, a bump via (BPV). The conductive bump 20 and/or the conductive via 40 may be formed of a material including, for example, copper. The conductive contact 30 may be formed of a material including, for example, copper. The seed layer 50 may be formed of a material including, for example, titanium nitride (TiN).

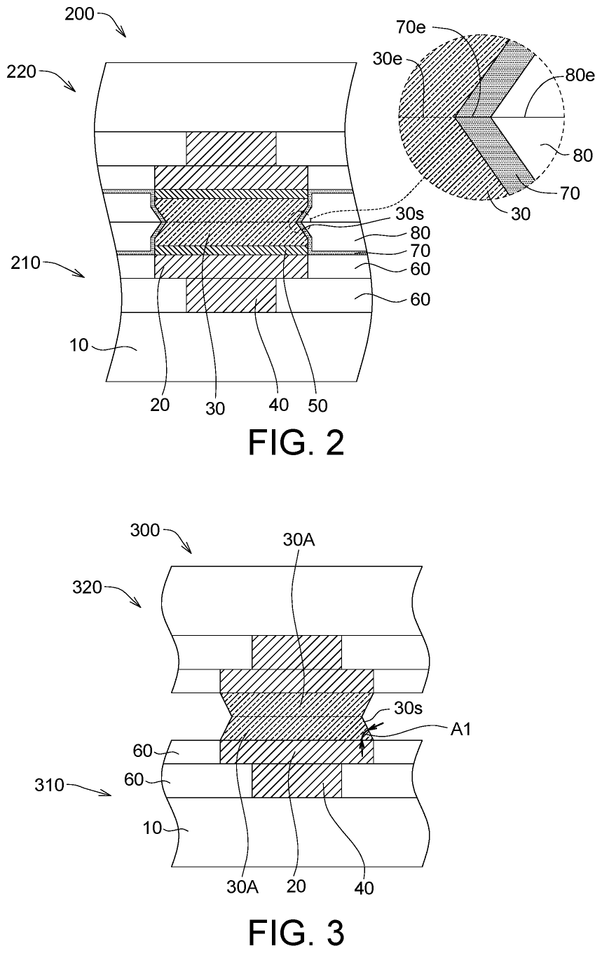

Referring to FIG. 2. FIG. 2 illustrates a schematic diagram of a semiconductor device 200 according to another embodiment of the present disclosure. The semiconductor device 200 includes a first semiconductor die 210 and a second semiconductor die 220. The first semiconductor die 210 and the second semiconductor die 220 may be connected by using bump-to-bump bonding technique or Cu-to-Cu bonding technique. Each of the first semiconductor die 210 and the second semiconductor die 220 includes the substrate 10, at least one conductive bump 20, at least one conductive contact 30, at least one conductive via 40, at least one seed layer 50, at least one dielectric layer 60, a covering layer 70 and at least one passivation layer 80.

The semiconductor device 200 includes the structures the same as or similar to that of the semiconductor device 100 except that, for example, the semiconductor device 200 further includes the covering layer 70 and the passivation layer 80. In an embodiment, the covering layer 70 may be formed of a material including, for example, SiCN, etc. The passivation layer 80 may be insulation layer.

As illustrated in FIG. 2, the covering layer 70 is formed on the dielectric layer 60 and covers the outer lateral sidewall 30s of the conductive contact 30. The covering layer 70 has a terminal surface 70e, and the conductive contact 30 has a terminal surface 30e, wherein the terminal surface 70e and the terminal surface 30e are flush with each other.

As illustrated in FIG. 2, the passivation layer 80 covers the covering layer 70. The passivation layer 80 has a terminal surface 80e, wherein the terminal surface 80e, the terminal surface 70e and the terminal surface 30e are flush with each other.

Referring to FIG. 3. FIG. 3 illustrates a schematic diagram of a semiconductor device 300 according to another embodiment of the present disclosure. The semiconductor device 300 includes a first semiconductor die 310 and a second semiconductor die 320. The first semiconductor die 310 and the second semiconductor die 320 may be connected by using bump-to-bump bonding technique or Cu-to-Cu bonding technique. Each of the first semiconductor die 310 and the second semiconductor die 320 includes the substrate 10, at least one conductive bump 20, at least one conductive contact 30A, at least one conductive via 40 and at least one dielectric layer 60.

As illustrated in FIG. 3, the semiconductor device 300 includes the structures the same as or similar to that of the semiconductor device 200 except that, for example, the semiconductor device 300 may omit the seed layer 50, and the conductive contact 30A may omit the base layer 31. In the present embodiment, the structure of the conductive contact 30A may be the same as that of the protrusion 32.

As illustrated in FIG. 3, the conductive contact 30A has the outer lateral sidewall 30s, there is the inner acute angle A1 included between the outer lateral sidewall 30s and the conductive bump 20 is smaller than 85°, and the conductive contact 30A of the first semiconductor die 310 is connected opposite to the conductive contact 30A of the second semiconductor die 320. In addition, the conductive contact 30A is a tapered contact.

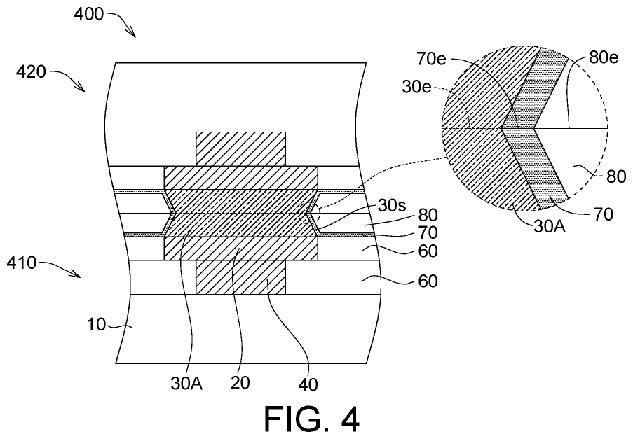

Referring to FIG. 4. FIG. 4 illustrates schematic diagram of a semiconductor device 400 according to another embodiment of the present disclosure. The semiconductor device 400 includes a first semiconductor die 410 and a second semiconductor die 420. The first semiconductor die 410 and the second semiconductor die 420 may be connected by using bump-to-bump bonding technique or Cu-to-Cu bonding technique. Each of the first semiconductor die 410 and the second semiconductor die 420 includes the substrate 10, at least one conductive bump 20, at least one conductive contact 30A, at least one conductive via 40, at least one dielectric layer 60, the covering layer 70 and at least one passivation layer 80.

The semiconductor device 400 includes the structures the same as or similar to that of the semiconductor device 300 except that, for example, the semiconductor device 400 further includes the covering layer 70 and the passivation layer 80.

As illustrated in FIG. 4, the covering layer 70 is formed on the dielectric layer 60 and covers the outer lateral sidewall 30s of the conductive contact 30A. The conductive contact 30A has the terminal surface 30e, and the covering layer 70 has the terminal surface 70e, wherein the terminal surface 70e and the terminal surface 30e are flush with each other.

As illustrated in FIG. 4, the passivation layer 80 covers the covering layer 70. The passivation layer 80 has the terminal surface 80e, wherein the terminal surface 80e, the terminal surface 70e and the terminal surface 30e are flush with each other.

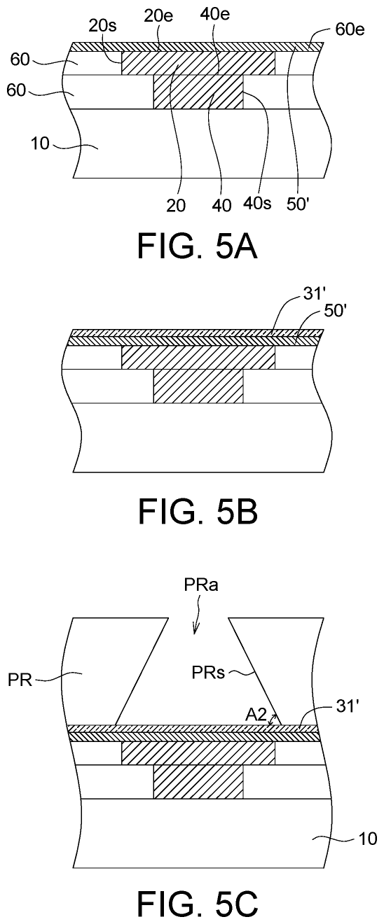

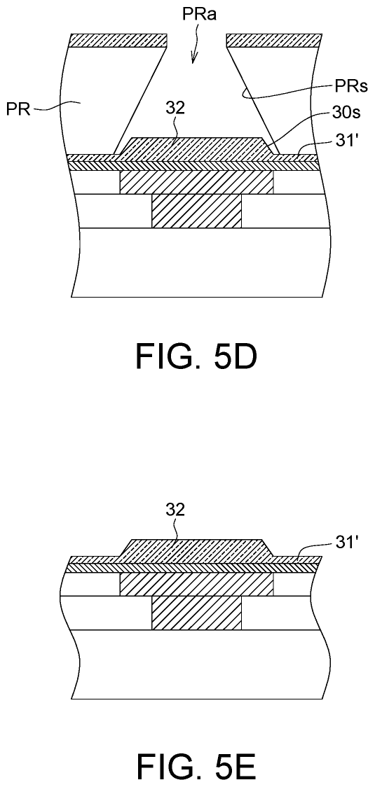

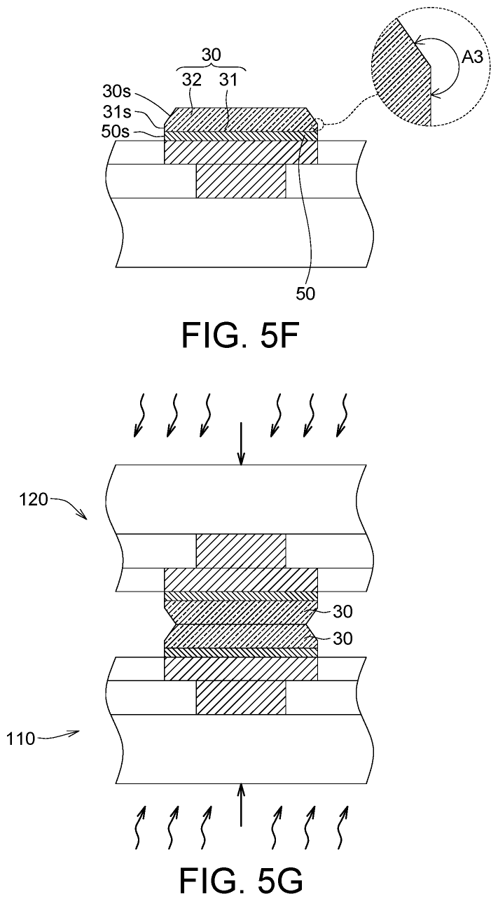

Referring to FIGS. 5A to 50, FIGS. 5A to 5G illustrate schematic diagrams of a manufacturing method of the semiconductor device 100 of FIG. 1A.

As illustrated in FIG. 5A, at least one dielectric layer 60, at least one conductive bump 20 and at least one conductive via 40 are formed on the substrate 10. The substrate 10 is, for example, a wafer. The conductive via 40 may electrically connect a Front End of Line (FEOL) circuit (not illustrated) and/or a Back End of Line (BEOL) circuit (not illustrated). The dielectric layer 60 covers a lateral surface 40s of the conductive via 40 and expose a terminal surface 40e of the conductive via 40. The conductive bump 20 is formed on the terminal surface 40e of the conductive via 40. The dielectric layer 60 covers a lateral surface 20s of the conductive bump 20 and exposes a terminal surface 20e of the conductive bump 20. In addition, the dielectric layer 60 may be formed by using, for example, photolithography including coating, exposure and/or developing (C/E/D), and the conductive bump 20 and the conductive via 40 may be formed by using, for example, electroplating.

In addition, the outermost dielectric layer 60 has a terminal surface 60e. The terminal surface 60e and the terminal surface 20e may be formed by using, for example, a CMP (Chemical-Mechanical Planarization). As a result, the terminal surface 60e and the terminal surface 20e are flush with each other for obtaining a seed layer material 50′ with high flatness'.

Then, as illustrated in FIG. 5A, the seed layer material 50′ is formed on the dielectric layer 60 and the conductive bump 20 by using, for example, a PVD (Physical Vapor Phase Deposition). The seed layer material 50′ is formed of a material including, for example, titanium (Ti), an alloy including Ti, etc.

As illustrated in FIG. 5B, a base layer material 31′ is formed on the seed layer material 50′ by using, for example, PVD. The base layer material 31′ may be formed of a material including, for example, copper. The base layer material 31′ has the fine metallographic structure due to PVD. Furthermore, the base layer material 31′ includes a plurality of grains, and each of at least one of the grains has the diameter ranging between 2 nm, 3 nm, 4 nm, 5 nm, 6 nm, 7 nm, 8 nm, 9 nm, 10 nm, 11 nm, 12 nm, . . . , 20 nm, . . . , 100 nm, etc.

As illustrated in FIG. 5C, a photoresist PR is formed on the base layer material 31′ (or the substrate 10) by using, for example, photolithography including coating, exposure and/or developing. The photoresist PR is, for example, lift-off type photoresist. The photoresist PR has at least one opening PRa having an inner lateral sidewall PRs, and there is an outer acute angle A2 included between the inner lateral sidewall PRs and the base layer material 31′ (or the substrate 10), wherein the outer acute angle A2 may be greater than 85°. The outer acute angle A2 may range between 55° and 85°, for example, 55°, 56°, 57°, 58°, 59°, 60°, 61°, 62°, 63°, 64°, 65°, 66°, 67°, 68°, 69°, 70°, 71°, 72°, 73°, 74°, 75°, 76°, 77°, 78°, 79°, 80°, 81°, 82°, 83°, 84°, 85°, etc.

If the outer acute angle A2 of the photoresist PR is greater than 85°, the photoresist PR contacts the subsequent conductive contact 30 of FIG. 5D and thus a stripping resistance between the conductive contact 30 and the photoresist PR is increased. If the outer acute angle A2 of the photoresist PR is smaller than 65°, the photoresist PR easily collapses.

As illustrated in FIG. 5D, the protrusion 32 is formed on the base layer material 31′ through the opening Pra by using, for example, PVD. The protrusion 32 may be formed of a material including, for example, copper. The protrusion 32 has the fine metallographic structure due to PVD. Furthermore, the protrusion 32 includes a plurality of grains, and each of at least one of the grains has the diameter ranging between 2 nm to 100 nm, such as 2 nm, 3 nm, 4 nm, 5 nm, 6 nm, 7 nm, 8 nm, 9 nm, 10 nm, 11 nm, 12 nm, . . . , 20 nm, . . . , 100 nm, etc. In addition, due to the outer acute angle A2 ranging between 55° and 85°, the photoresist PR may be successfully formed and does not collapse.

As illustrated in FIG. 5E, the photoresist PR is removed from the substrate 10 (or the base layer material 31′). Due to the inner lateral sidewall PRs of the photoresist PR not contacting with the outer lateral sidewall 30s of the protrusion 32, the photoresist PR may be easily removed by stripping.

As illustrated in FIG. 5F, a portion of the base layer material 31′ and a portion of the seed layer material 50′ are removed by using, for example, etching such as dry etching, wet etching, etc. A remaining portion of the base layer material 31′ and the protrusion 32 form the conductive contact 30. A remaining portion of the seed layer material 50′ forms the seed layer 50. In an embodiment, the seed layer 50 has a first lateral surface 50s, and the protrusion 32 has a second lateral surface 32s, wherein the lateral surface 50s and the lateral surface 31s are flush with each other. In addition, there is an outer obtuse angle A3 included between the lateral surface 31s of the base layer 31 and the outer lateral sidewall 30s of the protrusion 32, and the obtuse angle A3 is greater than 180°.

Then, the circuit wafer structure of FIG. 5F may be singulated to form at least one first semiconductor die 110 of FIG. 1A by using, for example, sawing.

The second semiconductor die 120 of FIG. 1A may be completed by using the method the same as or similar to that of the first semiconductor die 110.

As illustrated in FIG. 5G, the first semiconductor die 110 and the second semiconductor die 120 may be connected by bump-to-bump bonding to form the semiconductor device 100 of FIG. 1A. In a process of an embodiment, the conductive contact 30 of the first semiconductor die 110 and the conductive contact 30 of the second semiconductor die 120 may be connected by heating at a temperature ranging between 200° C., and 280° C., and pressuring at a force ranging between 1 Newton (N) and 5 N. Due to the conductive contact 30 having the fine metallographic structure, an excellent combination between the conductive contact 30 of the first semiconductor die 110 and the conductive contact 30 of the second semiconductor die 120 may be obtained even at a heating process (for example, annealing) with low temperature, for example, 200° C. to 260° C. After being bonded, there is no obvious interface between the conductive contacts 30; however, such exemplification is not meant to be for limiting.

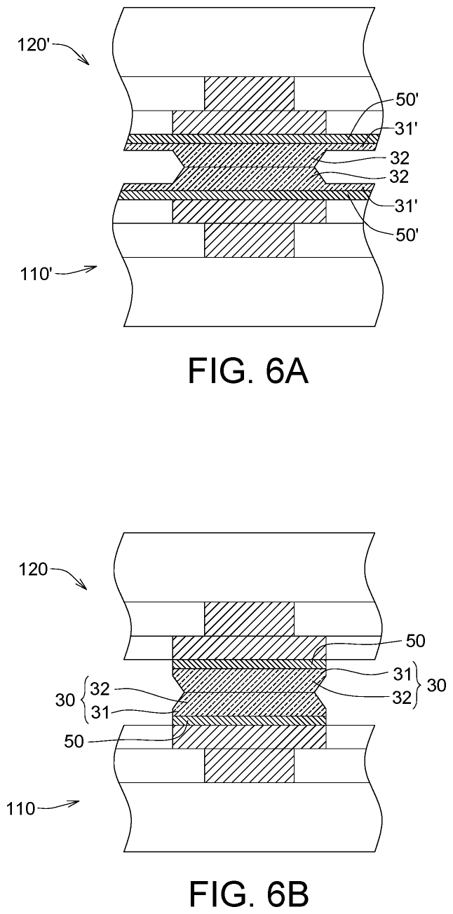

Referring to FIGS. 6A to 6B, FIGS. 6A to 611 illustrate schematic diagrams of another manufacturing method of the semiconductor device 100 of FIG. 1A.

As illustrated in FIG. 6A, after the protrusion 32 of FIG. 5E formed on the base layer material 31′ is formed, the protrusion 32 of a first structure 110′ (the structure the same as that of FIG. 5E) and the protrusion 32 of a second structure 120′ (formed by using the method the same as that of the structure 110′) are connected by bump-to-bump bonding technique similar to or the same as that of FIG. 50.

As illustrated in FIG. 6B, a portion of the base layer material 31′ of the first structure 110′ of FIG. 6A, a portion of the seed layer material 50′ of the first structure 110′ of FIG. 6A, a portion of the base layer material 31′ of the second structure 120′ of FIG. 6A and a portion of the seed layer material 50′ of the first structure 120′ of FIG. 6A are removed by using, for example, wet etching such as soaking process. A remaining portion of the of the base layer material 31′ forms the base layer 31, and a remaining portion of the seed layer material 50′ forms the seed layer 50. The base layer 31 and the protrusion 32 form the conductive contact 30.

Then, the conductive contact 30 of the first semiconductor die 110 and the conductive contact 30 of the second semiconductor die 120 may be connected by bump-to-bump bonding technique similar to or the same as that of FIG. 5G. So far, the semiconductor device 100 is completed.

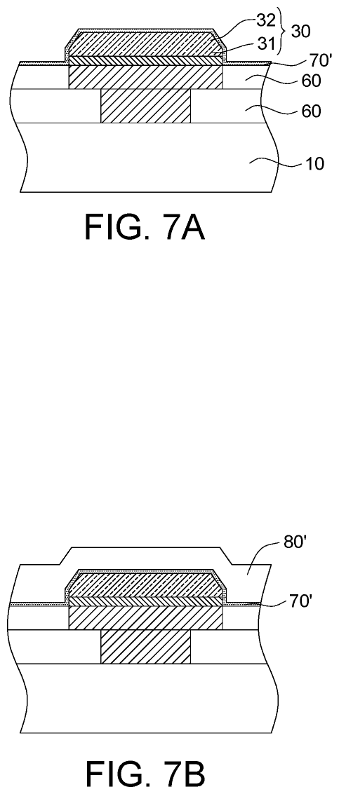

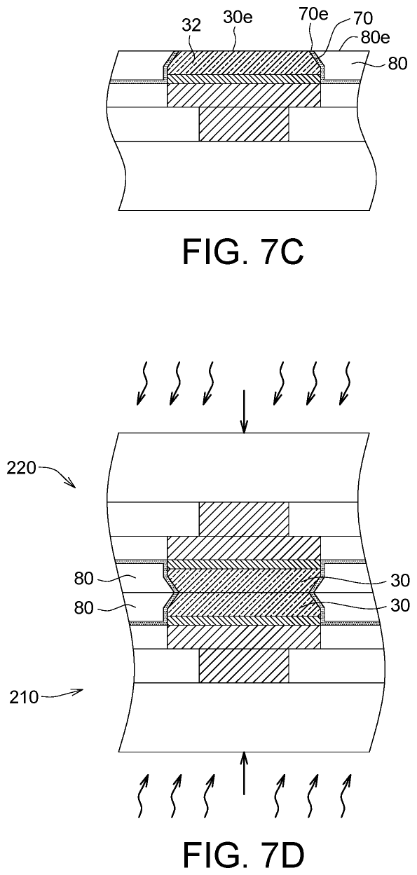

Referring to FIGS. 7A to 71). FIGS. 7A to 7D illustrate schematic diagrams of a manufacturing method of the semiconductor device 200 of FIG. 2. The conductive contact 30 of the first semiconductor die 210 may be formed by using the method the same as or similar to that of the conductive contact 30 of the first semiconductor die 110.

As illustrated in FIG. 7A, after the conductive contact 30 of FIG. 5F is formed, a covering layer material 70′ covering the conductive contact 30 and the dielectric layer 60 is formed by using, for example, deposition. The covering layer material 70′ may be formed of a material including, for example, SiCN.

As illustrated in FIG. 7B, a passivation layer material 80′ covering the covering layer material 70′ is formed by using, for example, HDP-CVD (High-Density Plasma-Chemical Vapor Deposition), etc.

As illustrated in FIG. 7C, a portion of the passivation layer material 80′ and a portion of the covering layer material 70′ are removed by using, for example, a CMP, and a remaining portion of the passivation layer material 80′ forms the passivation layer 80, and a remaining portion of the covering layer material 70′ forms the covering layer 70. After being removed, the protrusion 32 has the terminal surface 30e, the passivation layer 80 has the terminal surface 80e, and the covering layer 70 has the terminal surface 70e, wherein the terminal surface 80e, the terminal surface 70e and the terminal surface 30e are flush with each other.

Then, the circuit wafer structure of FIG. 7C may be singulated to form at least one first semiconductor die 210 of FIG. 2 by using, for example, sawing.

The second semiconductor die 220 of FIG. 2 may be completed by using the method the same as or similar to that of the first semiconductor die 210.

As illustrated in FIG. 7D, the first semiconductor die 210 and the second semiconductor die 220 may be connected by bump-to-bump bonding technique to form the semiconductor device 200 of FIG. 2. In a process of an embodiment, the passivation layer 80 of the first semiconductor die 210 and the passivation layer 80 of the second semiconductor die 220 may be connected by pressuring at a force smaller than 1 N or 5 N for 3 seconds to 5 seconds, and then heating (for example, pre-annealing) at a temperature of about 150° C. Then, the conductive contact 30 of the first semiconductor die 210 and the conductive contact 30 of the second semiconductor die 220 may be connected by heating (for example, annealing) at a temperature ranging between 200° C. and 280° C. for 4 hours to 10 hours. After being bonded, there is no obvious interface between the conductive contacts 30, there is no obvious interface between the covering layers 70 and/or there is no obvious interface between the passivation layers 80; however, such exemplification is not meant to be for limiting.

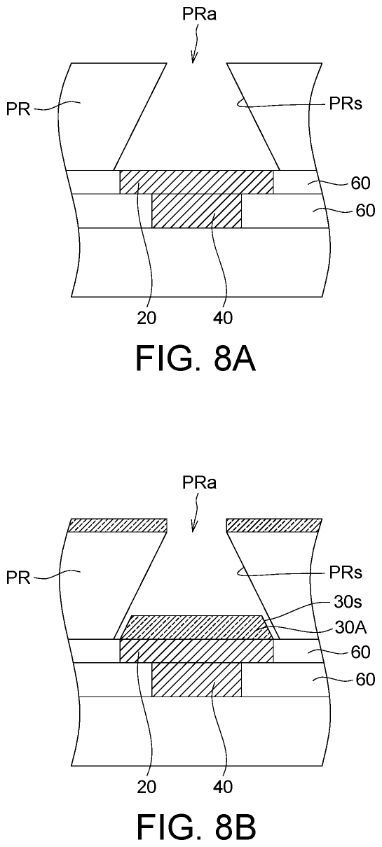

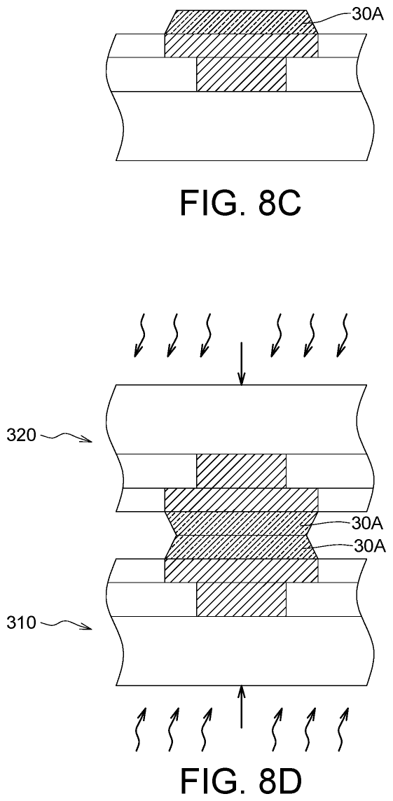

Referring to FIGS. 8A to 81, FIGS. 8A to 8D illustrate schematic diagrams of a manufacturing method of the semiconductor device 300 of FIG. 3.

As illustrated in FIG. 8A, at least one dielectric layer 60, at least one conductive bump 20 and at least one conductive via 40 are formed on the substrate 10. The substrate 10 is, for example, a wafer. Then, the photoresist PR is formed on the conductive bump 20 (or the substrate 10) by using, for example, photolithography including coating, exposure and/or developing.

The photoresist PR is, for example, lift-off type photoresist. The photoresist PR has at least one opening Pra having an inner lateral sidewall PRs, and there is the outer acute angle A2 included between the inner lateral sidewall PRs and the conductive bump 20 (or the substrate 10), wherein the outer acute angle A2 may be greater than 85°. The outer acute angle A2 may range between 55° and 85°, for example, 55°, 56°, 57°, 58°, 59°, 60°, 61°, 62°, 63°, 64°, 65°, 66°, 67°, 68°, 69°, 70°, 71°, 720, 73, 74°, 75°, 76°, 77°, 78°, 79°, 80°, 81°, 82°, 83°, 84°, 85°, etc.

If the outer acute angle A2 of the photoresist PR is greater than 85°, the photoresist PR contacts the subsequent conductive contact 30 of FIG. 5B and thus a stripping resistance between the conductive contact 30 and the photoresist PR is increased. If the outer acute angle A2 of the photoresist PR is smaller than 65°, the photoresist PR easily collapses.

As illustrated in FIG. 5B, the conductive contact 30A is formed on the conductive bump 20 through the opening Pra by using, for example, PVD. The conductive contact 30A may be formed of a material including, for example, copper. The conductive contact 30A has the fine metallographic structure due to PVD. Furthermore, the conductive contact 30A includes a plurality of grains, and each of at least one of the grains has the diameter ranging between 2 nm to 100 nm, such as 2 nm, 3 nm, 4 nm, 5 nm, 6 nm, 7 nm, 8 nm, 9 nm, 10 nm, 11 nm, 12 nm, . . . 20 nm, . . . , 100 nm, etc. In addition, due to the outer acute angle A2 ranging between 55° and 85°, the photoresist PR may be successfully formed and does not collapse.

As illustrated in FIG. 8C, the photoresist PR is removed from the substrate 10 (or the conductive bump 20). Due to the inner lateral sidewall PRs of the photoresist PR not contacting with the outer lateral sidewall 30s of the conductive contact 30A, the photoresist PR may be easily removed by stripping.

Then, the circuit wafer structure of FIG. 8C may be singulated to form at least one first semiconductor die 310 of FIG. 3 by using, for example, sawing.

The second semiconductor die 320 of FIG. 3 may be completed by using the method the same as or similar to that of the first semiconductor die 310.

As illustrated in FIG. 8D, the first semiconductor die 310 and the second semiconductor die 320 may be connected by bump-to-bump bonding technique similar to or the same as that of FIG. 5G. So far, the semiconductor device 300 of FIG. 3 is completed. After being bonded, there is no obvious interface between the conductive contacts 30; however, such exemplification is not meant to be for limiting.

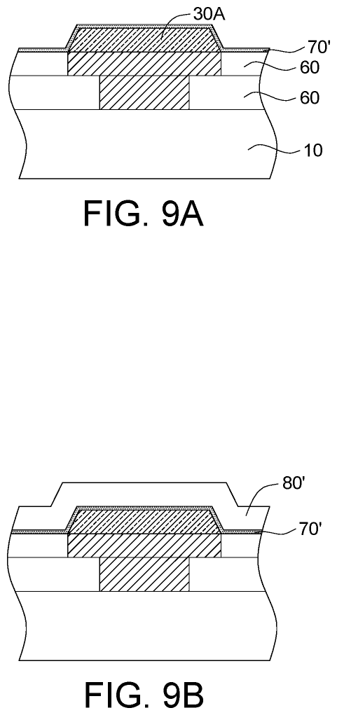

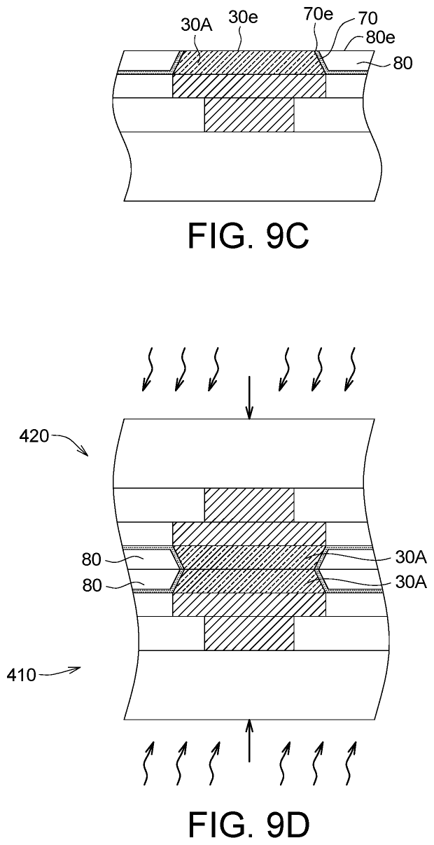

Referring to FIGS. 9A to 9D, FIGS. 9A to 9D illustrate schematic diagrams of a manufacturing method of the semiconductor device 400 of FIG. 4. The conductive contact 30A of the first semiconductor die 410 may be formed by using the method the same as or similar to that of the conductive contact 30A of the first semiconductor die 310.

As illustrated in FIG. 9A, after the conductive contact 30A of FIG. 8C is formed, the covering layer material 70′ covering the conductive contact 30A and the dielectric layer 60 is formed by using, for example, deposition. The covering layer material 70′ may be formed of a material including, for example, SiCN.

As illustrated in FIG. 9B, the passivation layer material 80′ covering the covering layer material 70′ is formed by using, for example, HDP-CVD, etc.

As illustrated in FIG. 9C, a portion of the passivation layer material 80′ and a portion of the covering layer material 70′ are removed by using, for example, a CMP, wherein a remaining portion of the passivation layer material 80′ forms the passivation layer 80, and a remaining portion of the covering layer material 70′ forms the covering layer 70. After being removed, the protrusion 30A has the terminal surface 30e, the passivation layer 80 has the terminal surface 80e, and the covering layer 70 has the terminal surface 70e, wherein the terminal surface 80e, the terminal surface 70e and the terminal surface 30e are flush with each other.

Then, the circuit wafer structure of FIG. 9C may be singulated to form at least one first semiconductor die 410 of FIG. 4 by using, for example, sawing.

The second semiconductor die 420 of FIG. 4 may be completed by using the method the same as or similar to that of the first semiconductor die 410.

As illustrated in FIG. 9D, the first semiconductor die 410 and the second semiconductor die 420 may be connected by bump-to-bump bonding technique similar to or the same as that of FIG. 5G. So far, the semiconductor device 400 of FIG. 4 is completed. After being bonded, there is no obvious interface between the conductive contacts 30, there is no obvious interface between the covering layers 70 and/or there is no obvious interface between the passivation layers 80; however, such exemplification is not meant to be for limiting.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor die includes a substrate and a conductive contact formed on the substrate. The conductive contact has an outer lateral sidewall, there is an inner acute angle included between the outer lateral sidewall. In an embodiment, the inner acute angle is smaller than 85°. Accordingly, in a process of forming the conductive contact, a photoresist having a corresponding angle may be successfully formed (prevented from collapsing) and is easily removed from the substrate.

Example embodiment 1: a semiconductor device includes a first semiconductor die and a second semiconductor die connected to the first semiconductor die. Each of the first semiconductor die and the second semiconductor die includes a substrate, a conductive bump formed on the substrate and a conductive contact formed on the conductive bump. The conductive contact has an outer lateral sidewall, there is an inner acute angle included between the outer lateral sidewall and the substrate is smaller than 85°, and the conductive contact of the first semiconductor die is connected opposite to the conductive contact of the second semiconductor die.

Example embodiment 2 based on Example embodiment 1: in one of the first semiconductor die and the second semiconductor die, the inner acute angle ranges between 55° and 85°.

Example embodiment 3 based on Example embodiment 1: in one of the first semiconductor die and the second semiconductor die, the conductive contact includes a plurality of grains, and each grain has a diameter ranging between 2 nm to 100 nm.

Example embodiment 4 based on Example embodiment 1; in one of the first semiconductor die and the second semiconductor die, the conductive contact of the first semiconductor die and the conductive contact of the second semiconductor die are connected in a connection, and the connection has a width ranging between 0.6 μm to 2.5 μm.

Example embodiment 5 based on Example embodiment 1: in one of the first semiconductor die and the second semiconductor die, the conductive contact has a width gradually decreasing in a direction away from the substrate.

Example embodiment 6 based on Example embodiment 1: in one of the first semiconductor die and the second semiconductor die, the conductive contact includes a base layer having a lateral surface; and a protrusion formed on the base layer and having the outer lateral sidewall. There is an outer obtuse angle included between the lateral surface of the base layer and the outer lateral sidewall, and the outer obtuse angle is greater than 180°.

Example embodiment 7 based on Example embodiment 1: in one of the first semiconductor die and the second semiconductor die, the conductive contact incudes a base layer having a base thickness; and a protrusion formed on the base layer and having a protrusion thickness. The protrusion thickness is 3 times to 10 times of the base thickness.

Example embodiment 8: a semiconductor device includes a first semiconductor die and a second semiconductor die connected to the first semiconductor die. Each of the first semiconductor die and the second semiconductor die includes a substrate, a conductive bump formed on the substrate, a seed layer formed on the conductive bump and a conductive contact formed on the seed layer. The conductive contact has an outer lateral sidewall, there is an inner acute angle included between the outer lateral sidewall and the substrate is smaller than 85°, and the conductive contact of the first semiconductor die is connected opposite to the conductive contact of the second semiconductor die.

Example embodiment 9 based on Example embodiment 8: in one of the first semiconductor die and the second semiconductor die, the inner acute angle ranges between 550 and 85°.

Example embodiment 10 based on Example embodiment 8: in one of the first semiconductor die and the second semiconductor die, the conductive contact has a protrusion thickness, the seed layer has a seed thickness, and the protrusion thickness is 3 times to 10 times of the seed thickness.

Example embodiment 11 based on Example embodiment 8: in one of the first semiconductor die and the second semiconductor die, the conductive contact includes a base layer having a base thickness; and a protrusion formed on the base layer and having a protrusion thickness. The protrusion thickness is 3 times to 10 times of the base thickness.

Example embodiment 12 based on Example embodiment 8: in one of the first semiconductor die and the second semiconductor die, the conductive contact includes a plurality of grains, and each grain has a diameter ranging between 2 nm to 100 nm.

Example embodiment 13 based on Example embodiment 8: in one of the first semiconductor die and the second semiconductor die, the conductive contact of the first semiconductor die and the conductive contact of the second semiconductor die are connected in a connection, and the connection has a width ranging between 0.6 μm to 2.5 μm.

Example embodiment 14 based on Example embodiment 8: in one of the first semiconductor die and the second semiconductor die, the conductive contact has a width gradually decreasing in a direction away from the substrate.

Example embodiment 15 based on Example embodiment 8: in one of the first semiconductor die and the second semiconductor die, the seed layer has a first lateral surface, the conductive contact has a second lateral surface, the first lateral surface and the second lateral surface are flush with each other.

Example embodiment 16: a manufacturing method of a semiconductor device includes the steps: forming each of a first semiconductor die and a second semiconductor die; and connecting a conductive contact of the first semiconductor die opposite to a conductive contact of the second semiconductor die. Forming each of the first semiconductor die and the second semiconductor die includes: forming a conductive bump on a substrate; forming a photoresist on the substrate, wherein the photoresist has an opening having an inner lateral sidewall, there is an outer acute angle included between the inner lateral sidewall and the substrate, and the outer acute angle is greater than 85°; and forming the conductive contact on the conductive bump through the opening of the photoresist, wherein the conductive contact has an outer lateral sidewall, there is an inner acute angle included between the outer lateral sidewall and the substrate is smaller than 85°.

Example embodiment 17 based on Example embodiment 16: forming each of the first semiconductor die and the second semiconductor die includes the steps: forming a base layer material on the substrate; forming the photoresist on the substrate; forming a protrusion on the base layer material through the opening of the photoresist; removing the photoresist from the substrate; and removing a portion of the base layer material, wherein a remaining portion of the base layer material forms the base layer, and the base layer and the protrusion form the conductive contact.

Example embodiment 18 based on Example embodiment 17: the base layer has a lateral surface, the protrusion has the outer lateral sidewall, there is an outer obtuse angle included between the lateral surface of the base layer and the outer lateral sidewall, and the outer obtuse angle is greater than 180°.

Example embodiment 19 based on Example embodiment 17: the protrusion has a protrusion thickness, the base layer has a base thickness, and the protrusion thickness is 3 times to 10 times of the base thickness.

Example embodiment 20 based on Example embodiment 16: forming each of the first semiconductor die and the second semiconductor die includes the steps: forming a seed layer material on the substrate; forming a base layer material on the seed layer material; forming a protrusion on the base layer material through the opening of the photoresist; and removing the photoresist from the substrate; and removing a portion of the base layer material and a portion of the seed layer material, wherein a remaining portion of the base layer material forms the base layer, a remaining portion of the seed layer material forms the seed layer, the seed layer has a first lateral surface, the base layer has a second lateral surface, the first lateral surface and the second lateral surface are flush with each other.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first semiconductor die; and
a second semiconductor die connected to the first semiconductor die;
wherein each of the first semiconductor die and the second semiconductor die comprises:
a substrate;
a conductive bump formed on the substrate;
a conductive contact formed on the conductive bump;
wherein the conductive contact has an outer lateral sidewall, there is an inner acute angle included between the outer lateral sidewall and the substrate is smaller than 85°, and the conductive contact of the first semiconductor die is connected opposite to the conductive contact of the second semiconductor die.

2. The semiconductor device as claimed in claim 1, wherein in one of the first semiconductor die and the second semiconductor die, the inner acute angle ranges between 55° and 85°.

3. The semiconductor device as claimed in claim 1, wherein in one of the first semiconductor die and the second semiconductor die, the conductive contact comprises a plurality of grains, and each grain has a diameter ranging between 2 nanometer (nm) to 100 nm.

4. The semiconductor device as claimed in claim 1, wherein in one of the first semiconductor die and the second semiconductor die, the conductive contact of the first semiconductor die and the conductive contact of the second semiconductor die are connected in a connection, and the connection has a width ranging between 0.6 micrometer (μm) to 2.5 μm.

5. The semiconductor device as claimed in claim 1, wherein in one of the first semiconductor die and the second semiconductor die, the conductive contact has a width gradually decreasing in a direction away from the substrate.

6. The semiconductor device as claimed in claim 1, wherein in one of the first semiconductor die and the second semiconductor die, the conductive contact comprises:
a base layer having a lateral surface; and
a protrusion formed on the base layer and having the outer lateral sidewall;
wherein there is an outer obtuse angle included between the lateral surface of the base layer and the outer lateral sidewall and the outer obtuse angle is greater than 180°.

7. The semiconductor device as claimed in claim 1, wherein in one of the first semiconductor die and the second semiconductor die, the conductive contact comprises:
a base layer having a base thickness; and
a protrusion formed on the base layer and having a protrusion thickness;
wherein the protrusion thickness is 3 times to 10 times of the base thickness.

8. A semiconductor device, comprising:
a first semiconductor die; and
a second semiconductor die connected to the first semiconductor die;
wherein each of the first semiconductor die and the second semiconductor die comprises:
a substrate;
a conductive bump formed on the substrate;
a seed layer formed on the conductive bump; and
a conductive contact formed on the seed layer;
wherein the conductive contact has an outer lateral sidewall, there is an inner acute angle included between the outer lateral sidewall and the substrate is smaller than 85°, and the conductive contact of the first semiconductor die is connected opposite to the conductive contact of the second semiconductor die.

9. The semiconductor device as claimed in claim 8, wherein in one of the first semiconductor die and the second semiconductor die, the inner acute angle ranges between 55° and 85°.

10. The semiconductor device as claimed in claim 8, wherein in one of the first semiconductor die and the second semiconductor die, the conductive contact has a protrusion thickness, the seed layer has a seed thickness, and the protrusion thickness is 3 times to 10 times of the seed thickness.

11. The semiconductor device as claimed in claim 8, wherein in one of the first semiconductor die and the second semiconductor die, the conductive contact comprises:
a base layer having a base thickness; and
a protrusion formed on the base layer and having a protrusion thickness;
wherein the protrusion thickness is 3 times to 10 times of the base thickness.

12. The semiconductor device as claimed in claim 8, wherein in one of the first semiconductor die and the second semiconductor die, the conductive contact comprises a plurality of grains, and each grain has a diameter ranging between 2 nm to 100 nm.

13. The semiconductor device as claimed in claim 8, wherein in one of the first semiconductor die and the second semiconductor die, the conductive contact of the first semiconductor die and the conductive contact of the second semiconductor die are connected in a connection, and the connection has a width ranging between 0.6 μm to 2.5 μm.

14. The semiconductor device as claimed in claim 8, wherein in one of the first semiconductor die and the second semiconductor die, the conductive contact has a width gradually decreasing in a direction away from the substrate.

15. The semiconductor device as claimed in claim 8, wherein in one of the first semiconductor die and the second semiconductor die, the seed layer has a first lateral surface, the conductive contact has a second lateral surface, the first lateral surface and the second lateral surface are flush with each other.

16. A manufacturing method of a semiconductor device, comprising:
forming each of a first semiconductor die and a second semiconductor die, comprising:
forming a conductive bump on a substrate;
forming a photoresist on the substrate, wherein the photoresist has an opening having an inner lateral sidewall, there is an outer acute angle included between the inner lateral sidewall and the substrate, and the outer acute angle is greater than 85°; and
forming a conductive contact on the conductive bump through the opening of the photoresist, wherein the conductive contact has an outer lateral sidewall, there is an inner acute angle included between the outer lateral sidewall and the substrate is smaller than 85°; and
connecting the conductive contact of the first semiconductor die opposite to the conductive contact of the second semiconductor die.

17. The manufacturing method as claimed in claim 16, wherein forming each of the first semiconductor die and the second semiconductor die comprises:
forming a base layer material on the substrate;
forming the photoresist on the substrate;
forming a protrusion on the base layer material through the opening of the photoresist;
removing the photoresist from the substrate; and
removing a portion of the base layer material, wherein a remaining portion of the base layer material forms the base layer, and the base layer and the protrusion form the conductive contact.

18. The manufacturing method as claimed in claim 17, wherein the base layer has a lateral surface, the protrusion has the outer lateral sidewall, there is an outer obtuse angle included between the lateral surface of the base layer and the outer lateral sidewall, and the outer obtuse angle is greater than 180°.

19. The manufacturing method as claimed in claim 17, wherein the protrusion has a protrusion thickness, the base layer has a base thickness, and the protrusion thickness is 3 times to 10 times of the base thickness.

20. The manufacturing method as claimed in claim 16, wherein forming each of the first semiconductor die and the second semiconductor die comprises:
forming a seed layer material on the substrate;
forming a base layer material on the seed layer material;
forming a protrusion on the base layer material through the opening of the photoresist;
removing the photoresist from the substrate; and
removing a portion of the base layer material and a portion of the seed layer material, wherein a remaining portion of the base layer material forms the base layer, a remaining portion of the seed layer material forms the seed layer, the seed layer has a first lateral surface, the base layer has a second lateral surface, the first lateral surface and the second lateral surface are flush with each other.
